(19) United States
(12) Patent Application Publication
(10) Pub. No.: US 2010/0052706 A1
(43) Pub. Date: Mar. 4, 2010

(54) CONSISTANT AND QUANTITATIVE METHOD FOR TCO DELAMINATION EVALUATION

(75) Inventors: LIZHONG SUN, San Jose, CA (US); Michel R. Frei, Palo Alto, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/548,608

(22) Filed: Aug. 27, 2009

Related U.S. Application Data
(60) Provisional application No. 61/093,294, filed on Aug. 29, 2008.

(51) Int. Cl. G01R 31/26

(52) U.S. Cl. 324/719

(57) ABSTRACT

A method and apparatus for manufacturing photovoltaic cells is provided. In one embodiment, a method for evaluating transparent conductive oxide (TCO) delamination from a substrate is provided. The method comprises providing a glass substrate with a TCO film laminated on a first surface of the glass substrate, depositing a metal layer on a second surface of the glass substrate opposite the first surface, heating the substrate while applying a bias to the substrate, cooling the substrate in a humidity controlled environment for a fixed time period, dividing the TCO film into a plurality of electrically insulated channels using a laser scribing process, and measuring a resistance of each of the plurality of electrically insulated channels.

### CROSS-REFERENCE TO RELATED APPLICATIONS

This application claims benefit of U.S. provisional patent application Ser. No. 61/093,294, filed Aug. 29, 2008, which is herein incorporated by reference.

### BACKGROUND OF THE INVENTION

1. Field of the Invention

Embodiments described herein generally relate to an apparatus and method for manufacturing of photovoltaic cells. More particularly, embodiments described herein generally relate to apparatus and methods for evaluation of transparent conductive oxide (TCO) delamination.

2. Description of the Related Art

Transparent conducting films (TCFs) for photovoltaic applications have been fabricated from both inorganic and organic materials. Inorganic films typically are made up of a layer of TCO generally in the form of indium tin oxide (ITO), fluorine doped tin oxide (FTO), tin oxide (SnO), or doped zinc oxide.

Transparent conducting films act both as a window for light to pass through to the active material beneath (where carrier generation occurs) and as an ohmic contact for carrier transport out of the photovoltaic. Transparent materials possess bandgaps with energies corresponding to wavelengths which are shorter than the visible range (380 nm to 750 nm). As such, photons with energies below the bandgap are not collected by these materials and thus visible light passes through.

Typically, TCO films are attached to a substrate using lamination processes. TCO delamination is a serious issue for solar modules. Delamination occurs when TCO laminated on glass is exposed to moisture and sodium ions in the glass move toward the interface between the TCO film and the glass substrate and interact with the moisture at the interface. These sodium ions break the bonds formed between the TCO film and the glass substrate. For photovoltaic module manufacturers, it is important to start with TCO glass, which has good delamination resistance in order to guarantee that the module will last for 25 to 30 years in the field. However, TCO delamination is generally a slow process and it is impractical to wait for 30 years to obtain field results in order to judge the delamination performance of a photovoltaic module. As a result, various methods have been developed to evaluate TCO delamination over a much shorter time frame.

In one known method, a sample comprising a glass substrate with a TCO layer deposited thereon is biased with a negative connection on the TCO layer while the exposed glass surface is heated on a hot plate. Metal indium is used as an electric contact between the hot plate and the exposed glass surface. After a fixed time period, the sample is cooled to room temperature in ambient. Then, the TCO delamination after moisture absorption is evaluated. Although this is a simple and quick evaluation method for TCO delamination, the method has several disadvantages making the test results less consistent and reliable. First, the distribution of melted indium on the exposed glass surface is non-uniform due to the high surface tension of indium on glass resulting in a non-uniform electric contact. Areas with poor electrical contact will not delaminate thus leading to skewed results. Second, cooling the test samples in an environment of varying humidity dependent on weather conditions leads to inconsistent results between samples. Finally, the evaluation method fails to provide a quantitative way to qualify TCO samples.

As a result, there is a need for an apparatus and method for evaluating TCO delamination on a substrate which provides consistent and accurate results over a short time frame.

### SUMMARY OF THE INVENTION

Embodiments described herein generally relate to an apparatus and method for manufacturing photovoltaic cells. More particularly, embodiments described herein generally relate to apparatus and methods for evaluation of transparent conductive oxides (TCO) delamination. In one embodiment, a method of evaluating transparent conductive oxide (TCO) delamination from a substrate is provided. The method comprises providing a glass substrate comprising a TCO film laminated on a first surface of the glass substrate and a metal layer deposited on a second surface of the glass substrate. The glass substrate is heated while applying a bias to the substrate. The heated substrate is exposed to a humidity controlled environment for a fixed time period. The TCO film is divided into a plurality of electrically insulated channels and the resistance of each of the plurality of electrically insulated channels is measured. The resistance of each of the plurality of electrically insulated channels is compared with a desired delamination resistance to determine which of the plurality of electrically insulated channels have suffered delamination and which of the plurality of electrically insulated channels are still functional. The TCO delamination from the substrate is evaluated by comparing a number of the plurality of electrically insulated channels that have suffered delamination with a number of the plurality of electrically insulated channels that are functional.

In another embodiment, a method for evaluating transparent conductive oxide (TCO) delamination from a substrate is provided. The method comprises providing a glass substrate with a TCO film laminated on a first surface of the glass substrate, depositing a metal layer on a second surface of the glass substrate opposite the first surface, heating the substrate while applying a bias to the substrate, cooling the substrate in a humidity controlled environment for a fixed time period, dividing the TCO film into a plurality of electrically insulated channels using a laser scribing process, and measuring a resistance of each of the plurality of electrically insulated channels.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart illustrating one embodiment of a method for evaluating transparent conductive oxide (TCO) delamination according to embodiments described herein;

FIG. 2A is a schematic side view of one embodiment of a TCO-laminated glass substrate according to embodiments described herein;

FIG. 2B is a schematic side view of one embodiment of a TCO-laminated glass substrate with a metal layer deposited thereon according to embodiments described herein;

FIG. 2C is a schematic side view of one embodiment of a TCO-laminated glass substrate being exposed to a heat source and a biasing source according to embodiments described herein;

FIG. 2D is a schematic side view of one embodiment of a TCO-laminated glass substrate being exposed to a humidity controlled environment according to embodiments described herein;

FIG. 2E is a schematic top view of one embodiment of a TCO-laminated glass substrate divided into a plurality of electrically insulated channels according to embodiments described herein; and

FIG. 2F is a schematic top view of the resistance of the electrically insulated channels of a TCO-laminated glass substrate being measured according to embodiments described herein.

### DETAILED DESCRIPTION

Embodiments described herein generally relate to apparatus and methods for evaluation of transparent conductive oxide (TCO) delamination. In one embodiment, a metal film with good affinity to glass was deposited on the exposed glass side of a TCO-laminated substrate as an electrical contact layer. The deposited metal layer improved the uniformity and stability of the electrical contact during subsequent biasing of the TCO-laminated substrate. In one embodiment, after heating in a temperature controlled environment and biasing the TCO-laminated substrate for a fixed time period, a humidifier was employed as a consistent moisture source for the TCO-laminated substrate. In one embodiment, after cooling the TCO-laminated substrate to room temperature, the TCO film was divided into several electrically insulated channels using laser scribing techniques, and the resistance of each individual channel was then determined. The resistance value and distribution over the each of the electrically insulated channels reflected the level of delamination. Therefore, TCO delamination was able to be quantitatively evaluated.

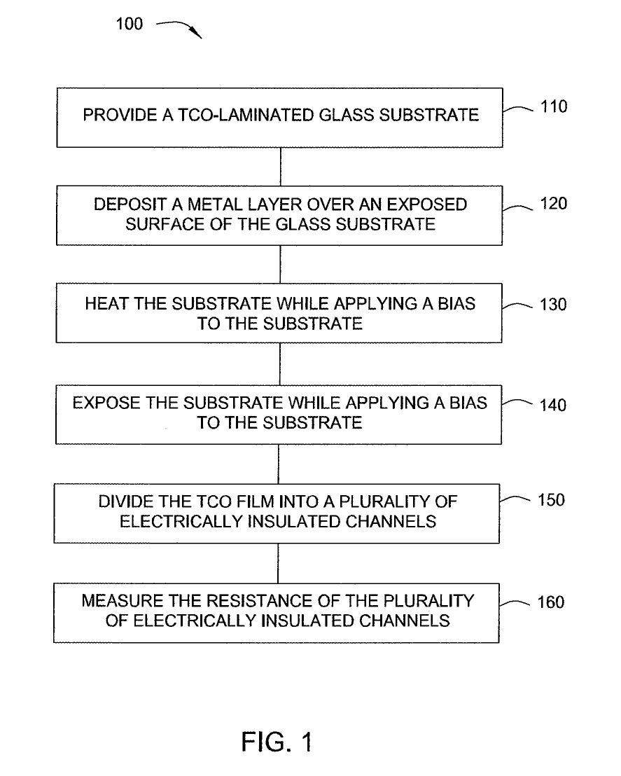

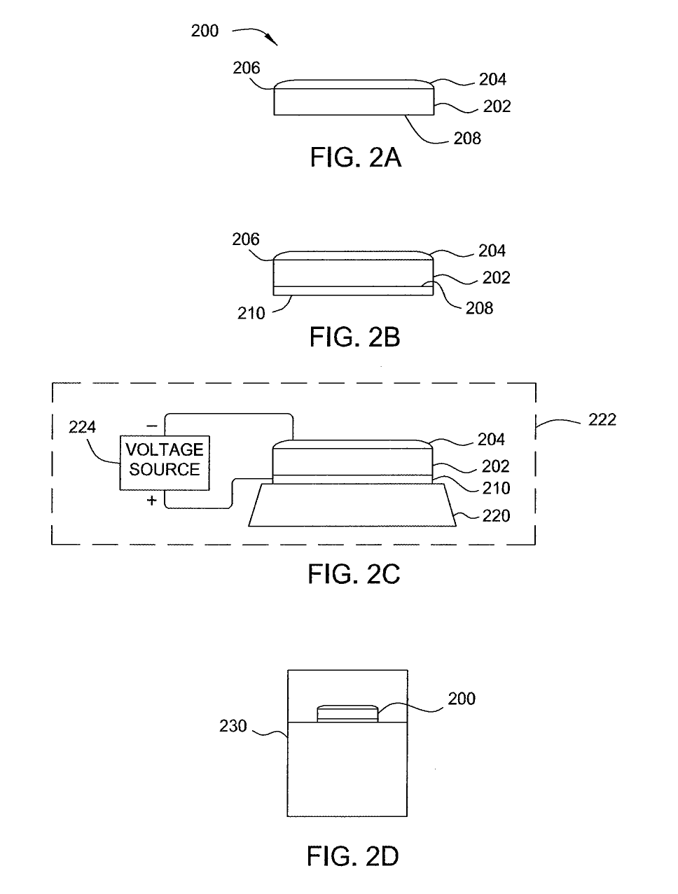

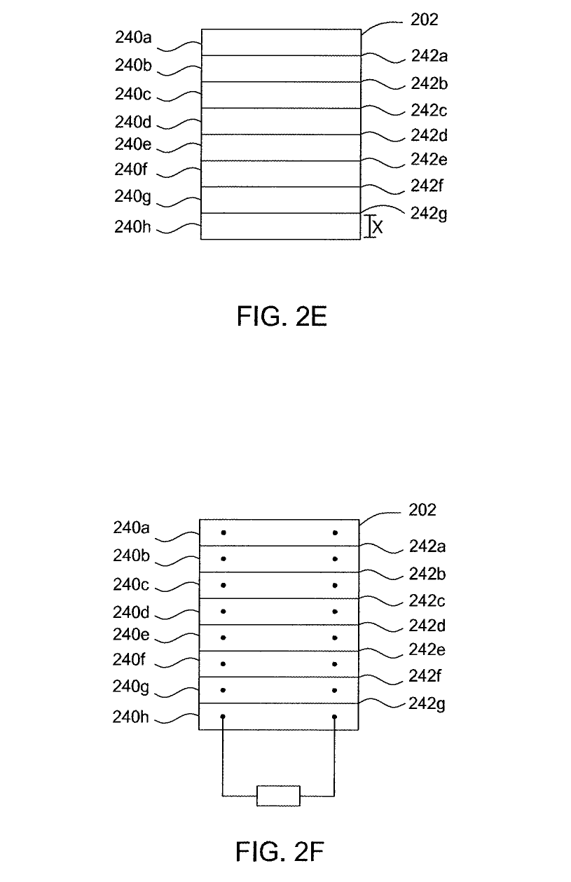

FIG. 1 is a flow chart 100 illustrating one embodiment of method for evaluating transparent conductive oxide (TCO) delamination according to embodiments described herein. FIGS. 2A-2F depict a TCO-laminated glass substrate 200 at various stages of the method for evaluating TCO delamination depicted in the flow chart 100 of FIG. 1. In block 110, a TCO-laminated glass substrate 200 is provided. As shown in FIG. 2A, the TCO-laminated glass substrate 200 comprises a glass substrate 202, a TCO film 204 deposited on a first surface 206 of the glass substrate 202, and a second exposed surface 208. In one embodiment, the TCO film 204 comprises material selected from the group comprising tin oxide (SnO), zinc oxide (ZnO), and aluminum doped zinc oxide (AZO).

In block 120, as shown in FIG. 2B, a metal layer 210 is deposited over the second exposed surface 208 of the TCO-laminated substrate 200 to provide uniform electrical contact and uniform heating of the TCO laminated substrate 200. In one embodiment, the metal layer 210 comprises aluminum. Metals such as aluminum have good affinity for glass thus providing uniform electrical contact. The thickness of the metal layer 210 is selected such that the metal layer 210 is thick enough to provide bulk conductivity and low resistivity. In one embodiment, the metal layer 210 has a thickness between about 1,000 Å and about 5,000 Å. In one embodiment, the metal layer 210 has a thickness between about 2,000 Å and about 3,000 Å. The metal layer 210 may be deposited using, for example, deposition techniques such as physical vapor deposition (PVD) techniques.

In block 130, as shown in FIG. 2C, the TCO-laminated glass substrate 200 is heated using a heating source 220 while a bias is applied to the substrate 200. The heating and biasing of the substrate may be controlled by modifying one or more of three parameters—time, temperature, and voltage. In one embodiment, the TCO-laminated glass substrate 200 is positioned on the heating source 220 such that the metal layer 210 is facing the heating source 220. In one embodiment, the heating source 220 comprises a hot plate. In one embodiment, the TCO-laminated substrate 200 is heated in an enclosed environment 222 such as an oven. Heating the TCO-laminated substrate 200 in an enclosed environment allows for greater temperature control. In one embodiment the substrate is heated to a temperature of between about 200° C. and about 300° C. In one embodiment the substrate 200 is heated to a temperature of between about 240° C. and about 260° C. In one embodiment the substrate is heated to a temperature of about 250° C.

In one embodiment, while the substrate 200 is being heated, the substrate 200 is exposed to a bias via a voltage source 224. In one embodiment, a negative bias is applied to the TCO film 204 and a positive bias is applied to the metal layer 210. In one embodiment, a voltage between about 50 volts and 500 volts is applied to the substrate 200. In one embodiment, a voltage of between about 100 volts and about 250 volts is applied to the substrate 200. In one embodiment a voltage of 100 volts is applied to the substrate 200. In one embodiment, a voltage of 250 volts is applied to the substrate 200. In one embodiment, the substrate 200 may be heated and biased for a time period of between about 5 minutes and about 15 minutes. In one embodiment, the substrate 200 may be heated and biased for a time period between about 6 minutes and about 10 minutes.

In one embodiment, heating of the substrate 200 and application of bias to the substrate 200 may overlap. For example, the substrate 200 may be heated without the application of bias for a first time period with the application of bias occurring simultaneously while heating the substrate for a second time period. Although described as a simultaneous process, it should be understood that in one embodiment heating of the substrate 200 and application of bias to the substrate 200 may occur as separate sequential steps.

In block 140, the TCO-laminated substrate 200 is exposed to a humidity controlled environment. In one embodiment, the substrate 200 is cooled to room temperature in the humidity controlled environment for a fixed time period. In one embodiment the fixed time period is between about 30 minutes and about 90 minutes. In one embodiment, the fixed time period is about 60 minutes. In one embodiment, the TCO laminated substrate 200 is positioned in an enclosed chamber 230 with a controlled relative humidity. In one embodiment, the humidity controlled environment is maintained at a relative humidity between about 60% and about 100%. In one embodiment, the humidity controlled environment is maintained at a relative humidity of between about 60% and about 80%.

In block 150, after removal of the substrate 200 from the humidity controlled environment, the TCO film 204 on the substrate 200 is divided into a plurality of electrically insulated channels 240a-h. In one embodiment, the substrate 200 is exposed to a laser scribing process to form scribe lines 242a-242g which define each channel 240a-h. Each channel 240a-h is generally of a uniform width “x”. In one embodiment the uniform width “x” is between about 1 mm and 4 mm. In one embodiment, the uniform width “x” is about 2 mm. It should be understood that although eight channels 240a-h are shown, that the substrate 200 may be divided into any number of electrically insulated channels 240a-h of any size depending not only on the size of the substrate being tested but also dependent upon the accuracy of the delamination evaluation desired. For example, evaluating a substrate containing a greater number of electrically insulated channels of a smaller width will increase the accuracy of the delamination results obtained in contrast with evaluation of a substrate of the same size but with fewer channels.

In block 160, the resistance of the plurality of electrically insulated channels 240a-h is measured. The resistance of each channel 240a-h is compared with a predetermined delamination resistance to determine which electrically insulated channels have suffered delamination and which electrically insulated channels are still functional. The surface of the substrate 200 may be evaluated by comparing the number of electrically insulated channels that have suffered delamination verses the number of electrically insulated channels which have not suffered delamination.

### EXAMPLES

The following non-limiting examples are provided to further illustrate embodiments described herein. However, the examples are not intended to be all inclusive and are not intended to limit the scope of the embodiments described herein.

### Comparative Example

The comparative example was performed using the know method discussed above. A sample comprising a glass substrate (NSG) with a TCO film deposited on one surface and an opposing exposed glass surface was provided. The TCO film was negatively charged at 500 volts. The sample was heated up to 170° C. for 15 minutes and the exposed glass surface contacted with indium during the test. The indium was in contact with the heated surface of a hot plate while heating. After heating for 15 minutes, the samples were cooled to room temperature and relative humidity. The TCO delamination after moisture absorption was evaluated. The TCO film on NSG SL demonstrated serious delamination during the hotplate test with indium as an electric contact to the glass substrate. However, due to the non-uniformity distribution of the indium layer on the surface of the glass substrate, the areas of the glass substrate without indium on the exposed glass surface did not show delamination. The resistance measurements indicated that the sheet resistance in the delaminated surface was >100 ohm/SQ and the non-delaminated area had similar sheet resistance to that of a new TCO sample.

### Representative Example

The representative example was performed using embodiments described herein. A sample comprising a glass substrate (NSG) with a TCO film deposited on one surface and an opposing exposed glass surface was provided. The TCO film was negatively charged at 100 volts while heating the sample to 160° C. for a period of 9 minutes and the exposed glass surface contacted with aluminum during the test. The aluminum was in contact with the heated surface of a hot plate while heating. After heating the sample for 9 minutes, the samples were cooled in a controlled environment of a relative humidity of 60%. The TCO delamination after moisture absorption was evaluated. The TCO film on NSG demonstrated uniform delamination during the hotplate test with aluminum as an electric contact to the glass substrate.

While the foregoing is directed to embodiments of the present invention, other and further embodiments of the invention may be devised without departing from the basic scope thereof, and the scope thereof is determined by the claims that follow.

1. A method of evaluating a transparent conductive oxide (TCO) delamination from a substrate, comprising:
providing a glass substrate comprising:
a TCO film laminated on a first surface of the glass substrate; and
a metal layer deposited on a second surface of the glass substrate;
heating the substrate while applying a bias to the substrate;
exposing the heated substrate to a humidity controlled environment for a fixed time period;
dividing the TCO film into a plurality of electrically insulated channels; and
measuring a resistance of each of the plurality of electrically insulated channels.

2. The method of claim 1, further comprising:
comparing the resistance of each of the plurality of electrically insulated channels with a desired delamination resistance to determine which of the plurality of electrically insulated channels have suffered delamination and which of the plurality of electrically insulated channels are still functional.

3. The method of claim 2, further comprising:
evaluating the TCO delamination from the substrate by comparing a number of electrically insulated channels that have suffered delamination with a number of electrically insulated channels that are functional.

4. The method of claim 1, wherein the TCO film comprises material selected from the group comprising tin oxide (SnO), zinc oxide (ZnO), and aluminum doped zinc oxide (AZO).

5. The method of claim 1, wherein heating the substrate comprises exposing the metal layer deposited on the second surface of the glass substrate to a heat source.

6. The method of claim 5, wherein applying a bias to the substrate comprises applying a positive bias to the metal layer and a negative bias to the TCO film.

7. The method of claim 5, wherein the heat source is positioned in an enclosed temperature controlled chamber.

8. The method of claim 1, wherein the metal layer is an aluminum layer.

9. The method of claim 1, wherein the fixed time period is selected to cool the substrate to room temperature.

10. A method for evaluating transparent conductive oxide (TCO) delamination from a substrate, comprising:
providing a glass substrate with a TCO film laminated on a first surface of the glass substrate;
depositing a metal layer on a second surface of the glass substrate opposite the first surface;
heating the substrate while applying a bias to the substrate;
cooling the substrate in a humidity controlled environment for a fixed time period;
dividing the TCO film into a plurality of electrically insulated channels using a laser scribing process;
measuring a resistance of each of the plurality of electrically insulated channels.

11. The method of claim 10, wherein the TCO film comprises material selected from the group comprising tin oxide (SnO), zinc oxide (ZnO), and aluminum doped zinc oxide (AZO).

12. The method of claim 10, wherein the metal layer is an aluminum layer.

13. The method of claim 12, wherein the metal layer has a thickness between about 1,000 Å and about 5,000 Å.

14. The method of claim 10, wherein heating the substrate comprises exposing the metal layer deposited on the second surface of the glass substrate to a heat source.

15. The method of claim 14, wherein applying a bias to the substrate comprises applying a bias between the metal layer and the TCO film.

16. The method of claim 10, wherein the humidity controlled environment is maintained at a relative humidity (RH) between about 60% and about 100%.

17. The method of claim 16, wherein heating the substrate comprises heating the substrate in a temperature controlled environment to a temperature of about 250° C.

18. The method of claim 15, wherein the bias is between about 100 volts to about 250 volts.

19. The method of claim 18, wherein the fixed time period is selected to cool the substrate to room temperature.

20. The method of claim 10, wherein cooling the substrate in a humidity controlled environment for a fixed time period comprises positioning the substrate in an enclosed chamber with a controlled relative humidity.
